(19) United States
(12) Patent Application Publication
(10) Pub. No.: US 2024/0065095 A1
(43) Pub. Date: Feb. 22, 2024

(54) COMPOSITION FOR ELECTRON TRANSPORTING LAYER AND METHOD FOR MANUFACTURING DISPLAY DEVICE INCLUDING THE SAME

(71) Applicant: Samsung Display Co., LTD., Yongin-si (KR)

(72) Inventors: Sang Hee YU, Yongin-si (KR); Gyu Bong KIM, Yongin-si (KR); Hoi Lim KIM, Yongin-si (KR); Se Hun KIM, Yongin-si (KR); Ju Yon LEE, Yongin-si (KR)

(73) Assignee: Samsung Display Co., LTD., Yongin-si (KR)

(21) Appl. No.: 18/119,986

(22) Filed: Mar. 10, 2023

(30) Foreign Application Priority Data
Aug. 4, 2022 (KR) 10-2022-0097414

(51) Int. Cl. H10K 85/60

(52) U.S. Cl. CPC H10K 85/60; H10K 50/16

(57) ABSTRACT

Embodiments provide a composition for an electron transporting layer and a method for manufacturing a display device including the same. The composition includes inorganic particles, peroxide, a hydrocarbon compound, and a solvent. A method for manufacturing a display device includes forming a first electrode on a substrate, forming a light emitting layer on the first electrode, forming an electron transporting layer on the light emitting layer, and forming a second electrode on the electron transporting layer, wherein the electron transporting layer is formed of a composition for an electron transporting layer including inorganic particles, peroxide, a hydrocarbon compound, and a solvent.

### CROSS-REFERENCE TO RELATED APPLICATION(S)

This application claims priority to and benefits of Korean Patent Application No. 10-2022-0097414 under 35 U.S.C. § 119, filed on Aug. 4, 2022, in the Korean Intellectual Property Office, the entire contents of which are incorporated herein by reference.

### BACKGROUND

### 1. Technical Field

The disclosure relates to a composition for an electron transporting layer and a method for manufacturing a display device including the same.

### 2. Description of the Related Art

As the information society develops, the demand for a display device for displaying an image is increasing in various forms. For example, the display device has been applied to various electronic devices such as smartphones, digital cameras, laptop computers, navigation devices, and smart televisions.

The display device may be a flat panel display device such as a liquid crystal display device, a field emission display device, or a light emitting display device. The light emitting display device may include an organic light emitting display device including an organic light emitting element and an inorganic light emitting display device including an inorganic light emitting element such as quantum dots.

Development of a display device including quantum dots among such display devices is in progress, and efforts to improve efficiency of the display device using the quantum dots are continuing.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a composition for an electron transporting layer capable of improving efficiency and a method for manufacturing a display device including the same.

However, aspects of the disclosure are not restricted to those set forth herein. The above and other aspects of the disclosure will become more apparent to one of ordinary skill in the art to which the disclosure pertains by referencing the detailed description of the disclosure given below.

According to an embodiment of the disclosure, a composition for an electron transporting layer may include inorganic particles, peroxide, a hydrocarbon compound, and a solvent.

In an embodiment, the peroxide may include at least one of dicumyl peroxide, cumene hydroperoxide, tert-butyl peroxide, benzoyl peroxide, tert-butyl peroxybenzoate, tert-butyl peracetate, and lauroyl peroxide.

In an embodiment, the hydrocarbon compound may include an alkane compound.

In an embodiment, a total content of the peroxide and the hydrocarbon compound may be in a range of about 1 wt % to about 30 wt % with respect to a total content of the solvent and the inorganic particles.

In an embodiment, the inorganic particles may include a metal oxide.

In an embodiment, a content of the inorganic particles may be in a range of about 0.1 wt % to about 5 wt % with respect to the solvent.

In an embodiment, the composition may further include at least one of a photoinitiator, a hydrocarbon compound including a double bond, and a hydrocarbon compound including acrylate.

In an embodiment, the composition further may include a photo acid generator or a thermal acid generator.

According to an embodiment of the disclosure, a method for manufacturing a display device may include forming a first electrode on a substrate, forming a light emitting layer on the first electrode, forming an electron transporting layer on the light emitting layer, and forming a second electrode on the electron transporting layer, wherein the electron transporting layer is formed of a composition for an electron transporting layer including inorganic particles, peroxide, a hydrocarbon compound, and a solvent.

In an embodiment, the light emitting layer may include a quantum dot including a core and a shell surrounding the core.

In an embodiment, in the forming of the electron transporting layer, the composition for an electron transporting layer may be applied on the light emitting layer, and a baking process may be performed.

In an embodiment, in the baking process, heat treatment may be performed at a temperature in a range of about 25 degrees Celsius to about 250 degrees Celsius.

In an embodiment, the baking process may include a first step of performing heat treatment at a temperature in a range of about 25 degrees Celsius to about 150 degrees Celsius, and a second step of performing heat treatment at a temperature in a range of about 150 degrees Celsius to about 250 degrees Celsius.

In an embodiment, in the first step, hydrogen radicals may be generated from the peroxide, and in the second step, the peroxide, the hydrocarbon compound, and the solvent may be removed.

In an embodiment, the inorganic particles may include a metal oxide, and in the composition for an electron transporting layer, a content of the inorganic particles may be in a range of about 0.1 wt % to about 5 wt % with respect to the solvent.

In an embodiment, the peroxide may include at least one of dicumyl peroxide, cumene hydroperoxide, tert-butyl peroxide, benzoyl peroxide, tert-butyl peroxybenzoate, tert-butyl peracetate, and lauroyl peroxide.

In an embodiment, the hydrocarbon compound may include an alkane compound.

In an embodiment, in the composition for an electron transporting layer, a total content of the peroxide and the hydrocarbon compound may be in a range of about 1 wt % to about 30 wt % with respect to a total content of the solvent and the inorganic particles.

In an embodiment, the composition for an electron transporting layer may further include: at least one of a photoinitiator, a hydrocarbon compound including a double bond, and a hydrocarbon compound including acrylate.

In an embodiment, the composition for an electron transporting may further include: a photo acid generator or a thermal acid generator.

In the composition for an electron transport layer and the method for manufacturing a display device including the same according to the embodiments, the composition for the electron transporting layer may include peroxide and a hydrocarbon compound to generate hydrogen radicals, so that the hydrogen radicals may be bound to the surface of the inorganic particles to modify the surface. Accordingly, a site where holes or electrons are trapped may be removed from the surface of the inorganic particles, thereby improving the efficiency of the light emitting element.

It is to be understood that the embodiments above are described in a generic and explanatory sense only and not for the purpose of limitation, and the disclosure is not limited to the embodiments described above.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating a display device according to an embodiment;

FIG. 2 is a schematic cross-sectional view illustrating a light emitting element of the display device according to an embodiment;

FIG. 3 is a schematic cross-sectional view illustrating a light emitting layer of the light emitting element according to an embodiment;

FIG. 4 is a schematic cross-sectional view illustrating a quantum dot of the light emitting element according to an embodiment;

FIGS. 5 to 8 are schematic views illustrating a method for manufacturing a display device according to an embodiment for each process; and

FIG. 9 is a graph illustrating efficiencies according to luminance of light emitting elements manufactured according to a comparative example and first to third experimental examples.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

It will be understood that the terms “connected to” or “coupled to” may refer to a physical, electrical and/or fluid connection or coupling, with or without intervening elements.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Each of the features of the various embodiments of the disclosure may be combined or combined with each other, in part or in whole, and technically various interlocking and driving are possible. Each embodiment may be implemented independently of each other or may be implemented together in an association.

Hereinafter, specific embodiments will be described with reference to the accompanying drawings.

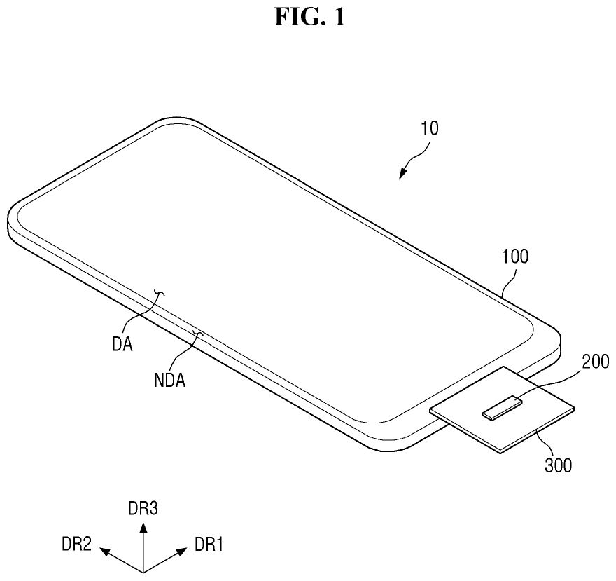

FIG. 1 is a schematic perspective view illustrating a display device according to an embodiment.

In the specification, “upper portion”, “top”, and “upper surface” refer to an upper direction with respect to a display panel 100, that is, one side in a third direction DR3, and “lower portion”, “bottom” and “lower surface” refer to a lower direction with respect to the display panel 100, that is, the other side in the third direction DR3.

A display device 10 is a device that displays a moving image or a still image, and may be used as a display screen of each of various products such as a television, a laptop computer, a monitor, a billboard, and Internet of Things (IOT) as well as portable electronic devices such as a mobile phone, a smartphone, a tablet personal computer (PC), a smartwatch, a watch phone, a mobile communication terminal, an electronic organizer, an electronic book, a portable multimedia player (PMP), a navigation device, and an ultra mobile PC (UMPC). The display device 10 may be any one of an organic light emitting display device, a liquid crystal display device, a plasma display device, a field emission display device, an electrophoretic display device, an electrowetting display device, a quantum dot light emitting display device, and a micro LED display device. Hereinafter, the display device 10 may be an organic light emitting display device, but the disclosure is not limited thereto.

Referring to FIG. 1, the display device 10 according to an embodiment includes a display panel 100, a display driving unit 200, and a circuit board 300.

The display panel 100 may be formed in a rectangular plane having a short side in a first direction DR1 and a long side in a second direction DR2 intersecting the first direction DR1. A corner where the short side in the first direction DR1 and the long side in the second direction DR2 meet may be rounded to have a given curvature or may be formed at a right angle. The planar shape of the display panel 100 is not limited to the rectangular shape, and may be other polygonal shapes, a circular shape, or an elliptical shape. The display panel 100 may be formed to be flat, but is not limited thereto, and may include curved portions formed at left and right ends and having a constant curvature or a varying curvature. The display panel 100 may be flexibly formed to be curved, bent, folded, or rolled.

The display panel 100 may include a display area DA in which sub-pixels are formed to display an image, and a non-display area NDA that is a peripheral area of the display area DA. When the display panel 100 includes the curved portion, the display area DA may be disposed on the curved portion. The image of the display panel 100 may be viewed even on the curved portion.

Each of the sub-pixels may include a driving transistor, at least one switching transistor, a light emitting element, and a capacitor. The transistor supplies a driving current to the light emitting element according to a data voltage applied to a gate electrode thereof, so that the light emitting element may emit light. The driving transistor and at least one transistor may be thin film transistors TFT. The light emitting element may emit light according to the driving current of the driving transistor. The light emitting element may be an organic light emitting diode including a first electrode, a light emitting layer, and a second electrode. The capacitor may serve to constantly maintain the data voltage applied to the gate electrode of the driving transistor.

The non-display area NDA may be defined as an area from the outside of the display area DA to an edge of the display panel 100. A scan driving unit for applying scan signals to the sub-pixels and pads may be disposed in the non-display area NDA. The circuit board 300 may be attached onto the pads, and the pads may be disposed on one side edge of the display panel 100, for example, a lower side edge of the display panel 100.

The display driving unit 200 receives digital video data and timing signals from the outside. The display driving unit 200 converts the digital video data into analog positive/negative data voltages and supplies the converted analog positive/negative data voltages to data lines. The display driving unit 200 generates and supplies a scan control signal for controlling an operation timing of the scan driving unit. The display driving unit 200 generates and supplies a light emitting control signal. The display driving unit 200 may supply a first driving voltage.

The display driving unit 200 may be formed as an integrated circuit (IC) and attached onto the circuit board 300 in a chip on film (COF) method. In an embodiment, the display driving unit 200 may be attached onto the display panel 100 by a chip on glass (COG) method, a chip on plastic (COP) method, or an ultrasonic bonding method.

The circuit board 300 may be attached onto the pads using an anisotropic conductive film. Accordingly, lead lines of the circuit board 300 may be electrically connected to the pads. The circuit board 300 may be a flexible film such as a flexible printed circuit board, a printed circuit board, or a chip on film.

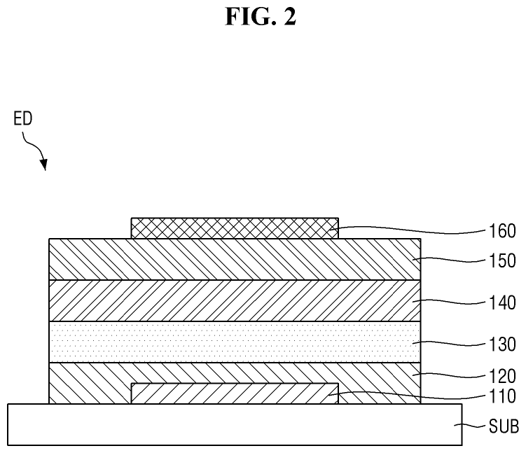

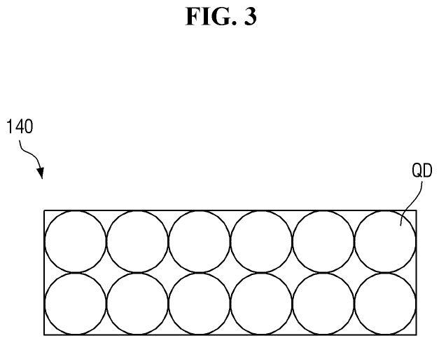

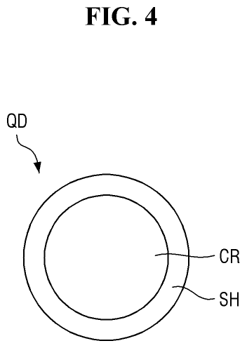

FIG. 2 is a schematic cross-sectional view illustrating a light emitting element of the display device according to an embodiment. FIG. 3 is a schematic cross-sectional view illustrating a light emitting layer of the light emitting element according to an embodiment. FIG. 4 is a schematic cross-sectional view illustrating a quantum dot of the light emitting element according to an embodiment.

Referring to FIGS. 2 to 4, a light emitting element ED according to an embodiment may include a first electrode 110, a hole injection layer 120, a hole transporting layer 130, a light emitting layer 140, an electron transporting layer 150, and a second electrode 160 disposed on a substrate SUB. Although not illustrated, an encapsulation layer for sealing the light emitting element ED may be further disposed on the second electrode 160.

The first electrode 110 may be an anode electrode of the light emitting element ED or a pixel electrode. The first electrode 110 may include indium tin oxide (ITO), indium zinc oxide (IZO), zinc oxide (ZnO), indium oxide (In₂O₃), and the like, and may include a transparent material having a high work function. When the first electrode 110 is a reflective electrode, the first electrode 110 may have a stacked structured in which a material layer having the high work function described above and a reflective material layer such as silver (Ag), magnesium (Mg), aluminum (Al), platinum (Pt), lead (Pd), gold (Au), nickel (Ni), neodymium (Nd), iridium (Jr), chromium (Cr), lithium (Li), calcium (Ca), or a mixture thereof are stacked. The material layer having the high work function may be disposed above the reflective material layer and disposed close to the light emitting layer 140. For example, the first electrode 110 may have a multilayer structure of ITO/Mg, ITO/MgF, ITO/Ag, and ITO/Ag/ITO, but is not limited thereto.

The hole injection layer 120 may be disposed on the first electrode 110. The hole injection layer 120 may serve to facilitate injection of holes from the first electrode 110 to the light emitting layer 140. The hole injection layer 120 may include, for example, a phthalocyanine compound such as copper phthalocyanine, DNTPD (N,N′-diphenyl-N,N′-bis-[4-(phenyl-m-tolyl-amino)-phenyl]-biphenyl-4,4′-diamine), m-MTDATA (4,4′,4″-[tris(3-methylphenyl)phenylamino]triphenylamine), TDATA (4,4′4″-Tris(N,Ndiphenylamino)triphenylamine), 2-TNATA (4,4′,4″-tris{N,-(2-naphthyl)-N-phenylamino}-triphenylamine), PEDOT/PSS (Poly(3,4-ethylenedioxythiophene)/Poly(4-styrenesulfonate)), PANI/DBSA (Polyaniline/Dodecylbenzenesulfonic acid), PANI/CSA (Polyaniline/Camphor sulfonicacid), PANI/PSS (Polyaniline/Poly(4-styrenesulfonate)), NPD(N,N′-di(naphthalene-l-yl)-N,N′-diphenylbenzidine), polyether ketone (TPAPEK) including triphenylamine, 4-Isopropyl-4′-methyldiphenyliodonium[Tetrakis(pentafluorophenyl)borate], HAT-CN (dipyrazino[2,3-f:2′,3′-h]quinoxaline-2,3,6,7,10,11-hexacarbonitrile), and the like.

The hole transporting layer 130 may be disposed on the hole injection layer 120. The hole transporting layer 130 may serve to facilitate injection of holes from the first electrode 110 to the light emitting layer 140. The hole transporting layer 130 may include, for example, carbazole-based derivatives such as N-phenylcarbazole and polyvinylcarbazole, fluorene-based derivatives, TPD (N,N′-bis(3-methylphenyl)-N,N′-diphenyl-[1,1-biphenyl]-4,4′-diamine), triphenylamine-based derivatives such as TCTA (4,4′,4″-tris(N-carbazolyl)triphenylamine), NPD (N,N′-di(naphthalene-l-yl)-N,N′-diphenyl-benzidine), TAPC (4,4′-Cyclohexylidene bis[N,Nbis(4-methylphenyl)benzenamine]), HMTPD (4,4′-Bis[N,N′-(3-tolyl)amino]-3,3′-dimethylbiphenyl), mCP (1,3-Bis(N-carbazolyl)benzene), and the like.

The hole injection layer 120 and the hole transporting layer 130 described above may each be formed by a vacuum deposition method, a spin coating method, a casting method, an inkjet printing method, a laser induced thermal imaging (LITI) method, or the like.

The hole injection layer 120 and the hole transporting layer 130 may have a thickness in the range of about 1 nm to about 500 nm. The thickness of the hole injection layer 120 and the hole transporting layer 130 may be, for example, each independently in a range of about 10 nm to about 100 nm. A thickness of the hole injection layer 120 may be, for example, in a range of about 1 nm to about 100 nm, and a thickness of the hole transporting layer 130 may be in a range of about 1 nm to about 100 nm. When the thickness of the hole injection layer 120 and the hole transporting layer 130 satisfies the range as described above, hole transport characteristics may be obtained without an increase in a driving voltage of the light emitting element ED.

The light emitting layer 140 may be disposed on the hole transporting layer 130. The light emitting layer 140 may include quantum dots QD.

The quantum dots QD may adjust the color of light emitted according to a particle size thereof, and accordingly, the quantum dots QD may have various light emitting colors such as blue, red, and green. As the size of the particle of the quantum dots QD is smaller, the quantum dots QD may emit light in a short wavelength region. For example, in the quantum dots QD having a same core, a particle size of a quantum dot emitting green light may be smaller than a particle size of a quantum dot emitting red light. In the quantum dots QD having a same core, a particle size of a quantum dot emitting blue light may be smaller than a particle size of a quantum dot emitting green light. However, the embodiment is not limited thereto, and even in the quantum dots QD having a same core, the size of the particle may be adjusted according to a material for forming a shell and a thickness of the shell. When the quantum dots QD have various light emitting colors such as blue, red, and green, the materials of the cores of the quantum dots QD having different light emitting colors may be different from each other.

The quantum dot QD may include a core CR and a shell SH surrounding the core CR. Although not illustrated, the quantum dot QD may further include a ligand bonded to a surface of the shell SH. The quantum dot QD may be in the form of a spherical nanoparticle, a pyramidal nanoparticle, a multi-arm nanoparticle, or a cubic nanoparticle, or the quantum dot QD may be in the form of a nanotube, a nanowire, a nanofiber, a nanoplatelet particle, and the like.

The core CR may be a semiconductor nanocrystal that may be selected from a Group XII-XVI compound, a Group XIII-XVI compound, a Group XIII-XV compound, a Group XIV-XVI compound, a Group XIV element, a Group XIV compound, and combinations thereof.

The Group XII-XVI compound may be selected from the group consisting of a binary compound selected from the group consisting of CdSe, CdTe, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of CdZnSeS, CdZnSeTe, CdZnSTe, CdHgSeS, CdHgSeTe, CdHgSTe, HgZnSeS, HgZnSeTe, HgZnSTe, and mixtures thereof.

The Group XIII-XVI compound may include a binary compound such as In₂S₃ or In₂Se₃, a ternary compound such as InGaS₃ or InGaSe₃, or any combination thereof.

The Group XIII-XV compound may be selected from the group consisting of a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, GaAlNP, and mixtures thereof, and a quaternary compound selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. The Group XIII-XV semiconductor compound may further include a group XII metal.

The Group XIV-XVI compound may be selected from the group consisting of a binary compound selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof.

The Group XIV element may be selected from the group consisting of Si, Ge, and mixtures thereof. A Group IV compound may be a binary compound selected from the group consisting of SiC, SiGe, and mixtures thereof.

The Group XI-XIII-XVI semiconductor compound may include a ternary compound such as AgInS, AgInS₂, CuInS, CuInS₂, CuGaO₂, AgGaO₂, or AgAlO₂, or any combination thereof.

The shell SH may serve as a protective layer for maintaining semiconductor properties by preventing chemical modification of the core CR and/or a charging layer for imparting electrophoretic properties to the quantum dot QD.

The shell SH may include a metal oxide, a non-metal oxide, a semiconductor compound, or a combination thereof. Examples of the metal oxide or the non-metal oxide may include, for example, a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, but the disclosure is not limited thereto. Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb, but the disclosure is not limited thereto.

A diameter of the core CR of the quantum dot QD may be in a range of about 1 nm to about 10 nm, but is not limited thereto. A thickness of the shell SH may be in a range of about 1 nm to about 10 nm, but is not limited thereto.

The quantum dots QD included in the light emitting layer 140 may be stacked to form a layer. Although it is illustrated in FIG. 3 that the quantum dots QD having a circular cross-section are arranged to approximately form two layers, the embodiment is not limited thereto. For example, the arrangement of the quantum dots QD may vary depending on a thickness of the light emitting layer 140, a shape of the quantum dots QD included in the light emitting layer 140, and an average diameter of the quantum dots QD. In the light emitting layer 140, the quantum dots QD may be aligned to be adjacent to each other to form one layer, or may be aligned to form layers such as two or three layers.

The electron transporting layer 150 may be disposed on the light emitting layer 140. The electron transporting layer 150 may serve to facilitate injection and transport of electrons from the second electrode 160 to the light emitting layer 140. A detailed description of the electron transporting layer 150 will be described later.

The second electrode 160 may be disposed on the electron transporting layer 150. The second electrode 160 may be a cathode electrode of the light emitting element ED. The second electrode 160 may include a material layer having a small work function, such as Li, Ca, LiF/Ca, LiF/Al, Al, Mg, Ag, Pt, Pd, Ni, Au, Nd, Ir, Cr, BaF, Ba, or compounds or mixtures thereof (e.g., a mixture of Ag and Mg, etc.). The second electrode 160 may further include a transparent metal oxide layer disposed on the material layer having the small work function.

The above-described electron transporting layer 150 may be formed of a composition for an electron transporting layer, and the composition for the electron transport layer may include inorganic particles, peroxide, a hydrocarbon compound, and a solvent.

The inorganic particles may serve to transport the electrons injected from the second electrode 160. The inorganic particles may include metal oxides. Examples of the metal oxide may include, for example, a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, SnO₂, Ta₂O₃, ZrO₂, HfO₂, or Y₂O₃, or a ternary compound such as ZnMgO, MgAl₂O₄, CoFe₂O₄, NiFe₂O₄, CoMn₂O₄, BaTiO₃, BaZrO₃, or ZrSiO₄, but the disclosure is not limited thereto.

The inorganic particles may be included in a range of about 0.1 wt % to about 5 wt % with respect to the solvent in the composition for the electron transporting layer. When the content of the inorganic particles is greater than or equal to about 0.1 wt % with respect to the solvent in the composition for the electron transporting layer, the inorganic particles may facilitate electron transport of the electron transporting layer, and when the content of the inorganic particles is less than or equal to about 5 wt % with respect to the solvent in the composition for the electron transporting layer, the inorganic particles may prevent the driving voltage of the light emitting element from being increased.

The peroxide reacts with the hydrocarbon compound to generate hydrogen (H) radicals, thereby modifying surfaces of the inorganic particles to improve element characteristics.

As a substance that may react with the hydrocarbon compound to generate hydrogen radicals, the peroxide may include at least one of, for example, dicumyl peroxide (DCP), cumene hydroperoxide (CHP), tert-butyl peroxide, benzoyl peroxide, tert-butyl peroxybenzoate, tert-butyl peracetate, and lauroyl peroxide.

Hereinafter, physical properties of the above-described peroxides are summarized in Table 1 below. In Table 1, resolution may indicate a rate of generation of radicals. The following physical properties were prepared based on when the solvent is benzene.

TABLE 1

| | | | Radical | |
|---|---|---|---|---|
| | | Autolysis | Generation | |
| Compound | | Temperature | Temperature | Resolution |
| Name | Chemical Structural Formula | (° C.) | (° C.) | (kd, (s⁻¹)) |
| Dicumyl Peroxide | 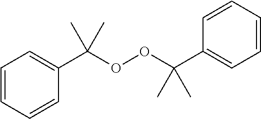 [SMILES: CC(C)(OOC(C)(C)c1ccccc1)c1ccccc1] | 80 | 135 | — |
| Cumene Hydroperoxide | 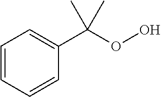 | 70 | 115 145 | 4.0 × 10⁻⁷ 6.6 × 10⁻⁶ |
| Tert-Butyl Peroxide | 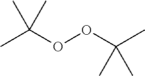 | 80 | 85 100 130 | 7.8 × 10⁻⁸ 8.8 × 10⁻⁷ 3.0 × 10⁻⁵ |
| Benzoyl Peroxide | 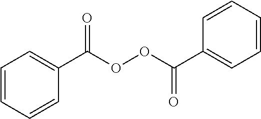 [SMILES: O=C(OOC(=O)c1ccccc1)c1ccccc1] | 80 | 60 78 100 | 2.0 × 10⁻⁶ 2.3 × 10⁻⁵ 5.0 × 10⁻⁴ |
| Tert-Butyl Peroxybenzoate | 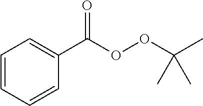 | 60 | 100 130 | 1.1 × 10⁻⁵ 3.5 × 10⁻⁴ |
| Tert-Butyl Peracetate | 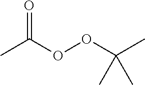 | 70 | 85 100 130 | 1.2 × 10⁻⁶ 1.5 × 10⁻⁵ 5.7 × 10⁻⁴ |
| Lauroyl Peroxide | 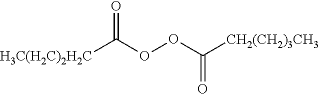 | 50 | 40 60 85 | 4.9 × 10⁻⁷ 9.2 × 10⁻⁶ 3.8 × 10⁻⁴ |

The hydrocarbon compound may react with the peroxide and may contribute to the generation of hydrogen radicals in the peroxide.

The hydrocarbon compound capable of reacting with the peroxide may be an alkane compound. Examples of the alkane compound may include, for example, methane, ethane, propane, butane, pentane, hexane, heptane, octane, nonane, decane, undecane, dodecane, tridecane, tetradecane, pentadecane, hexadecane, heptadecane, octadecane, nonadecane, icosane, triacontane, tetracontane, pentacontane, hexacontane, heptacontane, and the like. However, the disclosure is not limited thereto, and other compounds may also be used as long as it is an alkane compound.

A total content of the above-described peroxide and hydrocarbon compound may be in a range of about 1 wt % to about 30 wt % with respect to a total content of the solvent and inorganic particles in the composition for the electron transporting layer. When the total content of the peroxide and the hydrocarbon compound is greater than or equal to about 1 wt % with respect to a total content of the solvent and the inorganic particles in the composition for the electron transporting layer, it may be possible to improve the efficiency of the element by generating hydrogen radicals, and when the total content of the peroxide and the hydrocarbon compound is less than or equal to about 30 wt % with respect to a total content of the solvent and the inorganic particles in the composition for the electron transporting layer, it may be possible to prevent reliability from being deteriorated by the remaining residue.

The peroxide and the hydrocarbon compound may generate a hydrogen radical through beta (β)-scission as expressed in the following reaction formula by heat.

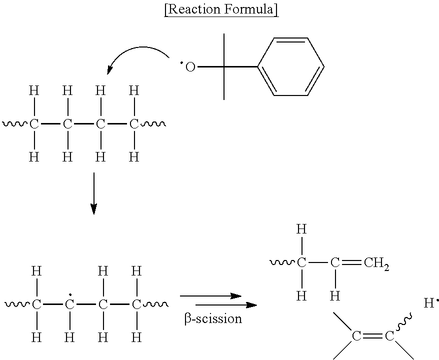

The hydrogen radicals generated by the reaction of the peroxide with the hydrocarbon compound may be bonded to surfaces of the inorganic particles, and may modify the surfaces of the inorganic particles to remove a site where holes or electrons are trapped. Accordingly, it may be possible to prevent the electrons injected into the light emitting layer from being trapped, thereby improving the efficiency of the element.

As the solvent, an organic solvent in which the inorganic particles, the peroxide, and the hydrocarbon compound may be dispersed may be used. Examples of the solvent may include, for example, hexane, toluene, chloroform, dimethyl sulfoxide, octane, xylene, hexadecane, cyclohexylbenzene, triethylene glycol monobutyl ether or dimethyl formamide decane, dodecane hexadecane, cyclohexylbenzene, tetrahydronaphthalene, ethylnaphthalene, ethylbiphenyl, isopropylnaphthalene, diisopropylnaphthalene, diisopropylbiphenyl, xylene, isopropylbenzene, pentylbenznene, diisopropylbenzene, decahydronaphthalene, phenylnaphthalene, cyclohexyldecahydronaphthalene, decylbenzene, dodecylbenzene, octylbenzene, cyclohexane, cyclopentane, cycloheptane, or the like.

The above-described composition for an electron transporting layer may further include at least one of a photoinitiator, a hydrocarbon compound including a double bond, and a hydrocarbon compound including acrylate to promote the generation of the hydrogen radicals.

The composition for the electron transporting layer may further include a compound capable of generating an acid. The compound capable of generating an acid is a compound that generates hydrogen ions (H+) upon UV irradiation, and may be, for example, a photo acid generator (PAG) or a thermal acid generator (TAG).

Examples of the photo acid generator may include, for example, diazonium salt-based compounds, phosphonium salt-based compounds, sulfonium salt-based compounds, iodonium salt-based compounds, imide sulfonate-based compounds, oxime sulfonate-based compounds, diazodisulfone-based compounds, disulfone-based compounds, ortho-nitrobenzylsulfonate-based compounds, triazine-based compounds, and the like.

Examples of the thermal acid generator may include, for example, diaryliodonium salts such as aryldiazonium salts and diphenyliodonium salts; di(alkylaryl)iodonium salts such as diaryliodonium salt and di(tert-butylphenyl)iodonium salt; trialkylsulfonium salts such as trimethylsulfonium salts; dialkyl monoaryl sulfonium salts such as dimethyl phenyl sulfonium salts; diaryl monoalkyl iodonium salts, such as diphenylmethyl sulfonium salts; triarylsulfonium salts, and the like.

According to an embodiment, the hydrogen ions generated from the compound capable of generating acid may be chemically bonded to the surface of the inorganic particle together with the above-described hydrogen radicals to modify the surface. According to an embodiment, it may be possible to remove a site where holes or electrons are trapped by modifying the surface of the inorganic particles. Accordingly, it may be possible to prevent the electrons injected into the light emitting layer from being trapped, thereby improving the efficiency of the element.

The composition for the electron transporting layer may also include polyethylene or polypropylene at an oligomer level instead of the hydrocarbon compound. The polyethylene or the polypropylene has a hydrocarbon chain and may thus act equivalently to the hydrocarbon compound described above.

Hereinafter, a method for manufacturing a display device according to an embodiment will be described with reference to other drawings.

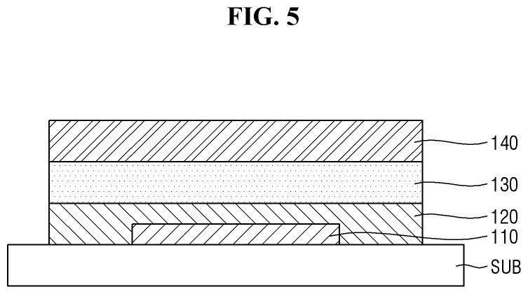

FIGS. 5 to 8 are schematic views illustrating a method for manufacturing a display device according to an embodiment for each process.

Referring to FIG. 5, a first electrode 110 may be formed on the substrate SUB. The first electrode 110 may be formed by stacking the above-described transparent material having the high work function and patterning the transparent material having the high work function using a photolithography method.

A hole injection layer 120 and a hole transporting layer 130 may be sequentially formed on the first electrode 110. The hole injection layer 120 and the hole transporting layer 130 may be formed by using various methods such as vacuum deposition method, a spin coating method, a casting method, a Langmuir-Blodgett (LB) method, an inkjet printing method, a laser printing method, and a laser induced thermal imaging (LITI) method. However, the disclosure is not limited thereto.

A light emitting layer 140 may be formed on the hole transporting layer 130. The light emitting layer 140 may be formed by applying a solution in which the above-described quantum dots (QD in FIG. 3) are dispersed in a solution process. The light emitting layer 140 may be formed by using various methods such as spin coating, casting, inkjet printing, and spraying as the solution process. For example, the light emitting layer 140 may be formed by coating and baking a solution in which the quantum dots are dispersed on the hole transporting layer 130 using an inkjet printing method.

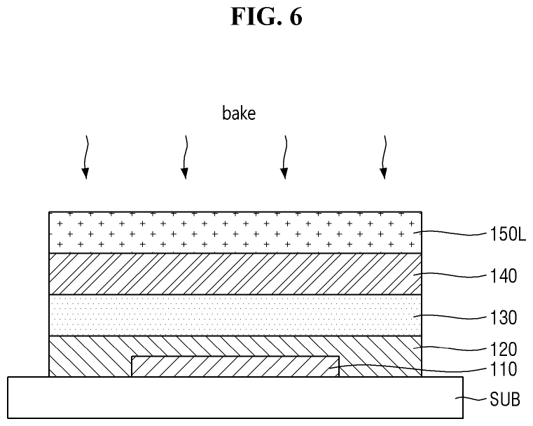

Referring to FIG. 6, a material layer 150L for a hole transporting layer may be applied on the light emitting layer 140. As the material layer 150L for the hole transporting layer, the above-described composition for the hole transporting layer may be used. The composition for the hole transporting layer may be prepared by mixing inorganic particles, peroxide, and a hydrocarbon compound in a solvent.

For example, in the preparation of the composition for the hole transporting layer, the inorganic particles may be mixed with the solvent in the solvent in a range of about 0.1 wt % to about 5 wt %. The composition for the hole transporting layer may be prepared by mixing and dispersing the peroxide and the hydrocarbon compound in a range of about 1 wt % to 30 wt % in the solvent.

A baking process of heat-treating the substrate SUB on which the material layer 150L for the hole transporting layer is formed is performed. The baking process may be a process in which the peroxide and the hydrocarbon compound are subjected to beta (β)-scission to generate hydrogen radicals, and the peroxide and the hydrocarbon compound are removed. The baking process may include a process in which the peroxide generates hydrogen radicals and thereafter the peroxide, the hydrocarbon compound, and the solvent are removed. To this end, in the baking process, a temperature may be increased from room temperature (e.g., about 25 degrees Celsius) to about 250 degrees Celsius at a constant temperature increase rate. In such a process, the peroxide and the hydrocarbon compound may generate hydrogen radicals at a given temperature and may be removed together with the solvent at a temperature exceeding a boiling point. For example, in the case of cumene hydroperoxide, as described above, the hydrogen radicals may be generated from about 115 degrees Celsius. As the baking temperature is increased, the hydrogen radicals may be generated from about 115 degrees Celsius, and the cumene hydroperoxide may be vaporized and removed when reaching about 250 degrees Celsius.

In another embodiment, the baking process may be performed in two steps. In a first step, heat treatment may be performed in a range of room temperature (e.g., about 25 degrees Celsius) to 150 degrees Celsius. The first step is a step of raising a temperature to a hydrogen radical generation temperature of the peroxide and maintaining the temperature for a given time. For example, since dicumyl peroxide generates hydrogen radicals at about 135 degrees Celsius, the temperature is maintained at about 150 degrees Celsius for several minutes to several tens of minutes so that the hydrogen radicals may be sufficiently generated.

In a second step, the hydrogen radicals may be generated and the peroxide, the hydrocarbon compound, and the solvent are removed. The second step may be a step of performing heat treatment in a range of about 150 to about 250 degrees Celsius. In such a process, the hydrogen radical generation by beta scission may be terminated, and the peroxide, the hydrocarbon compound, and the solvent may be removed. The reactants generated by the beta scission may also be removed, thereby preventing deterioration of element characteristics and deterioration of reliability due to their residual.

When the photoinitiator is further included in the composition for the electron transporting layer described above, a UV exposure process may be added before or after the baking process.

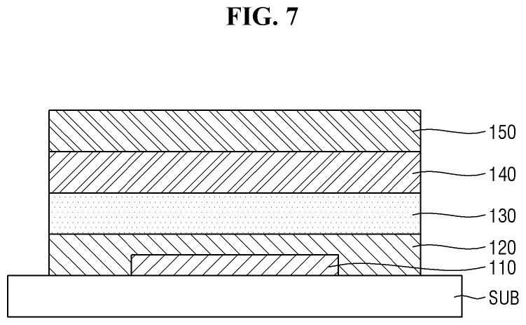

Referring to FIG. 7, when the above-described baking process is terminated, an electron transporting layer 150 including the inorganic particles may be manufactured on the light emitting layer 140. The electron transporting layer 150 may be in a state in which only inorganic particles may remain and other organic compounds such as the peroxide, the hydrocarbon compound, and the solvent are removed.

The previously generated hydrogen radicals may be bonded to the surface of the inorganic particles. The hydrogen radicals may modify the surface of the inorganic particle to remove a site where holes or electrons are trapped. Accordingly, it is possible to prevent the electrons injected into the light emitting layer from being trapped, thereby improving the efficiency and lifespan of the element.

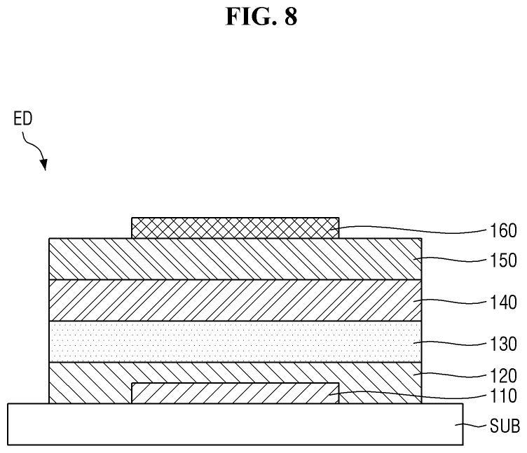

Referring to FIG. 8, the display device according to an embodiment may be manufactured by manufacturing a light emitting element ED by forming a second electrode 160 on the electron transporting layer 150.

Hereinafter, examples will be described in more detail through Comparative Examples and Experimental Examples.

### Comparative Example

A light emitting element was manufactured by sequentially forming ITO, a hole injection layer, a hole transporting layer, a light emitting layer including quantum dots, an electron transporting layer, and Al on a glass substrate. The electron transporting layer was manufactured by applying and baking a toluene solvent in which ZnMgO particles were dispersed in the content of 1 wt %.

### First Experimental Example

A light emitting device was manufactured in the same manner as in the above-described Comparative Example except that a composition for an electron transporting layer was manufactured by adding benzoyl peroxide and decane (solution) in a total content of 5 wt % to the toluene solvent in which ZnMgO particles were dispersed in a content of 1 wt %.

### Second Experimental Example

A light emitting element was manufactured using cumene hydroperoxide instead of benzoyl peroxide under the same conditions as in the First Experimental Example.

### Third Experimental Example

A light emitting element was manufactured using dicumyl peroxide instead of benzoyl peroxide under the same conditions as in the First Experimental Example.

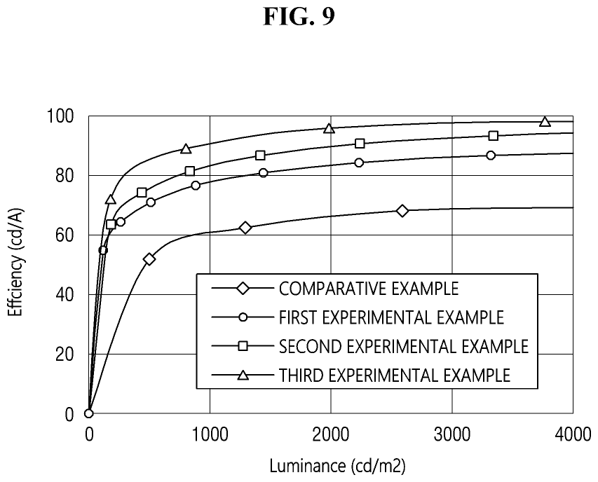

The efficiencies according to luminance of the light emitting elements manufactured according to the above described Comparative Example and First to Third Experimental Examples were measured and illustrated in FIG. 9.

FIG. 9 is a graph illustrating efficiencies according to luminance of light emitting elements manufactured according to a Comparative Example and First to Third Experimental Examples.

Referring to FIG. 9, the light emitting element according to the Comparative Example exhibited an efficiency of about 65 cd/A at a luminance of about 2000 cd/m². The light emitting element according to the First Experimental Example exhibited an efficiency of about 83 cd/A at a luminance of about 2000 cd/m². The light emitting element according to the Second Experimental Example exhibited an efficiency of about 90 cd/A at a luminance of about 2000 cd/m². The light emitting element according to the Third Experimental Example exhibited an efficiency of about 95 cd/A at a luminance of about 2000 cd/m².

Through this, it was found that the efficiencies of the light emitting elements according to the First to Third Experimental Examples were improved by about 30% or more compared to the light emitting element according to the Comparative Example.

As described above, the composition for the electron transporting layer according to an embodiment may include the peroxide and the hydrocarbon compound to generate the hydrogen radicals, so that the hydrogen radicals may be bound to the surface of the inorganic particles to modify the surface. Accordingly, the site where holes or electrons are trapped may be removed from the surface of the inorganic particles, thereby improving the efficiency of the light emitting element.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A composition for an electron transporting layer, the composition comprising:
inorganic particles;
peroxide;
a hydrocarbon compound; and
a solvent.

2. The composition of claim 1, wherein the peroxide includes at least one of dicumyl peroxide, cumene hydroperoxide, tert-butyl peroxide, benzoyl peroxide, tert-butyl peroxybenzoate, tert-butyl peracetate, and lauroyl peroxide.

3. The composition of claim 1, wherein the hydrocarbon compound includes an alkane compound.

4. The composition of claim 1, wherein a total content of the peroxide and the hydrocarbon compound is in a range of about 1 wt % to about 30 wt % with respect to a total content of the solvent and the inorganic particles.

5. The composition of claim 1, wherein the inorganic particles include a metal oxide.

6. The composition of claim 1, wherein a content of the inorganic particles is in a range of about 0.1 wt % to 5 wt % with respect to the solvent.

7. The composition of claim 1, further comprising:
at least one of a photoinitiator, a hydrocarbon compound including a double bond, and a hydrocarbon compound including acrylate.

8. The composition of claim 1, further comprising:
a photo acid generator or a thermal acid generator.

9. A method for manufacturing a display device, the method comprising:
forming a first electrode on a substrate;
forming a light emitting layer on the first electrode;
forming an electron transporting layer on the light emitting layer; and
forming a second electrode on the electron transporting layer, wherein
the electron transporting layer is formed of a composition for an electron transporting layer including inorganic particles, peroxide, a hydrocarbon compound, and a solvent.

10. The method of claim 9, wherein the light emitting layer includes a quantum dot including a core and a shell surrounding the core.

11. The method of claim 9, wherein
in the forming of the electron transporting layer, the composition for an electron transporting layer is applied on the light emitting layer,
and a baking process is performed.

12. The method of claim 11, wherein in the baking process, heat treatment is performed at a temperature in a range of about 25 degrees Celsius to about 250 degrees Celsius.

13. The method of claim 12, wherein the baking process includes:
a first step of performing heat treatment at a temperature in a range of about 25 degrees Celsius to about 150 degrees Celsius; and
a second step of performing heat treatment at a temperature in a range of about 150 degrees Celsius to about 250 degrees Celsius.

14. The method of claim 13, wherein
in the first step, hydrogen radicals are generated from the peroxide, and
in the second step, the peroxide, the hydrocarbon compound, and the solvent are removed.

15. The method of claim 9, wherein
the inorganic particles include a metal oxide, and
in the composition for an electron transporting layer, a content of the inorganic particles is in a range of about 0.1 wt % to about 5 wt % with respect to the solvent.

16. The method of claim 9, wherein the peroxide includes at least one of dicumyl peroxide, cumene hydroperoxide, tert-butyl peroxide, benzoyl peroxide, tert-butyl peroxybenzoate, tert-butyl peracetate, and lauroyl peroxide.

17. The method of claim 9, wherein the hydrocarbon compound includes an alkane compound.

18. The method of claim 9, wherein in the composition for an electron transporting layer, a total content of the peroxide and the hydrocarbon compound is in a range of about 1 wt % to about 30 wt % with respect to a total content of the solvent and the inorganic particles.

19. The method of claim 9, wherein the composition for an electron transporting layer further includes:
at least one of a photoinitiator, a hydrocarbon compound including a double bond, and a hydrocarbon compound including acrylate.

20. The method of claim of 9, wherein the composition for an electron transporting layer further includes:
a photo acid generator or a thermal acid generator.
